(19) United States
(12) Patent Application Publication
(10) Pub. No.: US 2007/0249926 A1
(43) Pub. Date: Oct. 25, 2007

(54) Magnetic Field Gradients Adapted to Position of Region Being Imaged

(75) Inventors: Ian Leitch McDougall, Oxon (GB); Peter Hanley, Gloucestershire (GB)

Correspondence Address: MAINE & ASMUS, 100 MAIN STREET, P O BOX 3445, NASHUA, NH, 03061-3445, US

(73) Assignee: OXFORD INSTRUMENTS PLC, Oxford (GB)

(21) Appl. No.: 10/595,429

(22) PCT Filed: Oct. 21, 2004
(86) PCT No.: PCT/GB04/04457

§ 371 Date: Feb. 5, 2007

(30) Foreign Application Priority Data
Oct. 22, 2003 (GB) 0324646.9

(51) Int. Cl. G01R 33/385

(52) U.S. Cl. 600/410

(57) ABSTRACT

A magnetic resonance apparatus comprises a magnet system for generating a magnetic field in a working volume. Magnetic gradient coils are used to generate one or more magnetic field gradients in the working volume so as to define regions from which magnetic resonance signals are obtained from a target material. A controller operates the gradient coils in use so as to apply one or more magnetic field gradients within each region. For each of the defined regions, the controller performs a method in which the one or more magnetic field gradients are controlled in accordance with the position of the said region with respect to the gradient coils, such that the one or more magnetic field gradients have a predetermined uniformity, thereby increasing the uniformity within regions at the periphery of the working volume.

### FIELD OF THE INVENTION

The present invention relates to a method of operating a magnetic resonance apparatus, along with such magnetic resonance apparatus itself.

### BACKGROUND OF THE INVENTION

The principles of magnetic resonance are now widely used as part of various techniques to obtain information from within target structures. Such information can take a number of forms including spectroscopic and imaging information. This has led to the development of magnetic resonance imaging (MRI), which is now an invaluable tool in the field of medicine.

Various magnetic resonance system configurations are known although each of these attempt to produce a substantially homogeneous magnetic field “working region” within which the target of interest is placed.

Magnetic field gradient coils or “gradient coils” are used in addition to a main field magnet. In a typical MRI procedure a constant, strong magnetic induction B₀ is applied with the main magnet. By convention, B₀ is in the z direction: \vec{B}₀=(0,0,B_{0z}). Superimposing linear, spatial gradients of magnetic induction on this enables the spatial mapping of nuclear magnetic resonance (NMR) sensitive properties such as density, via the frequency or phase of the NMR signal. A great many techniques have been devised to perform these measurements.

Typically, a “slice” of the subject is selected by the application of a gradient in a direction perpendicular to the plane of the slice together with a radiofrequency (RF) pulse of appropriate frequency. A two-dimensional image of the slice is then produced using switched gradients to encode the spatial information in the frequency and phase of the NMR signal.

The gradients which are required are:

$${G}_{x} = \frac{\partial {B}_{z}}{\partial x} , {G}_{y} = \frac{\partial {B}_{z}}{\partial y} , {G}_{z} = \frac{\partial {B}_{z}}{\partial z}$$

In order to perform the MRI procedure effectively, the gradient coils must have certain properties:

Strength:

A sufficient gradient strength is needed to ensure that the magnetic induction change across a pixel is greater than the B₀ inhomogeneity, given by

$$G \times \frac{L}{N} \geq δ {B}_{0}$$

where L is the size of the field of view (FOV) and N is the number of pixels.
Uniformity:

The gradients should be reasonably linear so that importantly, the strength of the magnetic induction produced by the gradient must be everywhere single-valued over the volume from which the signal are received in order to prevent “aliasing”.

Rise time:

It must be possible to switch the gradients quickly (typically in a millisecond or less). The reasons for this are:

a) an appropriate subset of measurements may be made in a time short compared with the longitudinal relaxation time (Tₗ); and

b) a complete image or set of images can be acquired in a time which is not inconveniently long.

In order to achieve short rise times, it is necessary to minimise the stored energy (½LI²) otherwise the current supply requirements become unreasonable. In general it is to be expected that a trade off exists between achieving good uniformity and a low stored energy. Uniformity can be improved by increasing the size of the coil system relative to the working region volume, but the stored energy can be expected to increase as the fifth power of the linear dimensions. In the case of “single sided” systems this conflict can be expected to be especially severe because of the lack of symmetry about the centre of the FOV. A single sided system is one in which primarily the equipment is on one side of the working volume, allowing approximately 4Π steradians of solid-angle access.

Some known approaches to gradient coil designs are summarised by Turner in “Gradient Coil Design: A Review of Methods”, Magnetic Resonance Imaging, Vol. 11, pp903-920, 1993. An “openable” set of gradient coils is described by Crozier et. al. in “An ‘Openable’ High Strength Gradient Set for Orthopedic MRI”, Journal of Magnetic Resonance, 139, pp81-89, 1999. Notably, in all of these descriptions, the coil systems possess a high degree of symmetry which lends itself to the achievement of uniformity without incurring penalties of high inductance or stored energy.

Magnetic resonance methods are therefore extremely complicated technologically and require very precise control of the magnetic fields used. Such fields are often very strong, in particular the B₀ field. Ideally it is desirable to produce a magnetically uniform working region. It is also desirable that such a working region is as large as possible with respect to the magnetic system with which it is generated, since the physical size of the system often introduces high costs and complexity, particularly where superconducting magnet systems are used.

In view of this it is therefore desirable to obtain the very highest quality of signal information possible by using not only a working region with a very homogeneous magnetic field, but also gradient fields which can be applied throughout the working region.

In reality such a working region does not have a sharp and defined boundary, and rather the level of homogeneity in the vicinity of the working region drops off as function of the distance away from the centre of the working region. A conceptual region can be defined within which an acceptable level of homogeneity is provided, although it will be understood that even at the boundary of this region, the level of homogeneity is less than that at the centre. Similar comments apply to the magnetic field gradients.

In particular the most uniform gradients are provided at the centre of a working volume, whereas those towards the edge are degraded in quality by comparison. It is therefore desirable to provide ever increasing working region volumes, and similarly to provide high quality gradients at all points within such volumes.

### SUMMARY OF THE INVENTION

In accordance with a first aspect of the present invention we provide a method of operating a magnetic resonance apparatus in which magnetic gradient coils are used to generate one or more magnetic field gradients in a working volume so as to define regions from which magnetic resonance signals are obtained in use from a target material; characterised in that, for each of the defined regions, the one or more magnetic field gradients are controlled in accordance with the position of the said region with respect to the gradient coils, so as to apply one or more magnetic field gradients of predetermined uniformity within the region.

We have realised that magnetic gradient coils can be used to great advantage in a manner which has not been previously considered, that is they can be controlled to provide a gradient which is tailored to the position of the particular region (such as a “slice”) with respect to the coils. This is quite different to prior art systems where no such consideration of the position of the region within the working volume is made. Indeed, in such known systems, similar gradient pulse sequences are provided for all regions. The present invention therefore provides for the tailoring of the magnetic field gradient in accordance with its position with respect to the gradient coils and accordingly with respect to its position within the working volume.

The regions may correspond to slices whose plane is perpendicular to the x, y, or z axes, or slices formed at angles to any of these axes. If the imaging technique so permits, the regions may also be positioned at different locations within the slices themselves. Such techniques may be those which obtain information a line at a time, or point-by-point. Clearly if the technique obtains information from the whole slice at the same time (typically two-dimensional Fourier transform methods) then the region over which the gradient is optimised is limited to being no smaller than a single slice.

Whilst gradient coils in known systems are designed so as to provide the most constant gradients at the centre of the working region, traditionally any degradation due to the position of regions away from such a centre is merely tolerated. Gradient coils in known systems are therefore normally symmetrically positioned in pairs with respect to the working region and the currents within such complementary coils are of equal magnitude, albeit sometimes of opposite polarity.

The present invention recognises that, by breaking this symmetry, gradients of improved quality can be provided in regions that are spaced away from the centre of the working region. This may be achieved according to the present invention by the independent control of the gradient coils themselves.

A set of at least two magnetic gradient coils are therefore preferably provided for producing the magnetic field gradient in a particular direction and preferably therefore the method comprises controlling the ampere-turns values within the at least two coils of the set independently. For a set comprising more than two coils, independent control can be applied to at least two of them, each of them or any intermediate number. Typically such coils are provided in pairs or at least an even number of coils, although in some new configurations with greater asymmetry, a set may comprise an odd number of coils. It will be appreciated that the ampere-turns values can be controlled by controlling the current within the coils and/or the number of turns used in such coils.

With a suitable controllable current supply, it is possible to conveniently provide different current values within the coils. Similarly, the number of turns within the coils can be effectively increased or decreased by the use of switching apparatus to include further turns. Switchable sub-coils can be used which act together in use as a single coil.

Depending on the particular configuration of the magnetic resonance apparatus, the defined regions may take various forms. The most commonly used region geometry is that of a slice as is known in connection with MRI using a solenoid magnet. However, other forms may be used with the invention, the basic requirement being that such regions can be added together so as to substantially intersect the volume of interest without substantial volumes between them. The defined regions may be arranged as a series of regions, each having a complementary geometry with respect to an adjacent region, such that the combined volume of the regions substantially intersects a target volume of interest. Here the geometries may be complementary in that the bounding opposing surfaces of adjacent regions are conformal. Alternatively, the regions are arranged to overlap.

For a particular region, therefore, the one or more magnetic field gradients applied to that region are normally dissimilar to those applied to an adjacent region. This is typically the case in regions at the periphery of the working volume whereas those adjacent the centre may require no adjustment of the ampere-turns at all, or only minor adjustments, to achieve a “high quality” sufficiently constant gradient.

The primary advantage of such control is that effectively the working region itself can be expanded since higher quality signals can be obtained from a larger volume.

In principle therefore, the present invention can be used and provide advantage with virtually any known magnetic resonance apparatus. However, although there are benefits in using the invention with symmetrical systems (such as with a solenoid magnet), an important advantage arises with the use of the invention in more asymmetrical systems.

There is an ever-increasing interest in the possibility of producing true “open-access” MRI systems in which medical patients are not required to be enclosed within the bore of a solenoid magnet. Ideally, it is desirable for the patient to be able to simply lie upon a table with the magnetic resonance apparatus being arranged so as to allow the patient free movement upon the table. One such potential solution to this problem is the provision of a “single sided” system in which all, or at least the majority of the magnetic apparatus is provided upon one side of such a table, preferably either above or below it.

Unfortunately, the inherent asymmetry of such a system requires that in order to produce a working volume of the required homogeneity, numerous large and powerful magnets are needed. Since such magnets are positioned primarily upon one side of the working volume then it is extremely difficult to achieve a homogeneous field in a particular direction within the volume. Such problems also apply to the magnetic gradient fields used to produce magnetic resonance imaging in such regions. With the present invention, such asymmetry problems can be addressed and therefore the method provides particular application in situations where the working volume is arranged to one side of the coils.

It will be appreciated that the present invention is therefore applicable to gradient coils for not only slice selection purposes (often along the Z-axis), but also for the frequency encoding and phase encoding gradient coils, these being used to produce spatial information within a selected slice. These gradient coils can be used to improve the gradients within the particular slice from which information is being obtained. Therefore the method preferably further comprises controlling not only the slice-selection gradient coils but also those producing gradients perpendicular to the slice-selection gradient so as to improve the gradients over the selected slice.

In this case the regions are typically arranged along a Z-axis defining the magnetic field direction of the magnetic resonance apparatus. Within a particular region, the magnetic field gradients are controlled along an X-axis and/or a Y-axis, the X and Y axes being substantially orthogonal to the Z-axis.

In accordance with a second aspect of the present invention we also provide a magnetic resonance apparatus comprising:

a magnet system for generating a magnetic field in a working volume;

magnetic gradient coils for generating one or more magnetic field gradients in the working volume so as to define regions from which magnetic resonance signals are obtained from a target material; and

a controller for operating the magnetic gradient coils in use so as to apply one or more magnetic field gradients within each region, characterised in that

for each of the defined regions, the controller is further adapted in use to control the one or more magnetic field gradients in accordance with the position of the said region with respect to the gradient coils, such that the one or more magnetic field gradients have a predetermined uniformity.

Typically therefore a set of at least two magnetic gradient coils are provided for producing the magnetic field gradient in a first direction allowing the ampere-turns values of each of the at least two of the said coils to be independently controllable. In order to provide this advantage as a function of position within the region itself, preferably a set of at least two magnetic gradient coils are provided for producing the magnetic field gradient in each of, a second direction, or a second and third direction respectively, wherein for each set the ampere-turn values of at least two of the said coils are independently controllable.

The gradient coils are also preferably arranged as part of the magnetic apparatus such that the defined regions comprise a series of regions, each having a complementary geometry with respect to an adjacent region such that the combined volume of the regions substantially intersects a target volume of the target material.

In the case of asymmetrical systems such as single-sided systems, preferably the working volume is arranged on one side of the coils comprising the magnetic resonance systems, and wherein the regions are arranged in the working volume. Although an even number of coils, arranged in pairs, are preferably provided for symmetrical systems, for asymmetrical systems such as single sided magnet systems, the gradient coils are typically each arranged along a common direction, that is such that their axes are parallel. In some configurations the coils may each be provided co-axially although such coils are not necessarily co-planar (their centres being positioned at different points along the axis). Such coaxial coils are of great advantage in single-sided systems since they reduce the resultant stored energy when the coils are in use.

Whilst switching apparatus may be used so as to provide additional turns using a similar current, preferably the apparatus further comprises a controllable current supply for providing current independently to the at least two magnetic gradient coils within each coil set.

### BRIEF DESCRIPTION OF THE DRAWINGS

Some examples of a method and apparatus for magnetic resonance according to the present invention are now described with reference to the accompanying drawings, in which:

FIG. 1a shows the arrangement of two pairs of gradient coils according to a first example;

FIG. 1b shows a control system for the coils;

FIG. 2 is a graph showing the magnetic field in the z direction according to the gradient coils of the first example;

FIG. 3 shows gradient coils for a single sided system according to a second example;

FIG. 4 is a graph showing the gradient of the z component magnetic field in the z direction according to the first example;

FIG. 5 is a graph showing the gradient of the z component magnetic field in the x direction according to the first example;

FIG. 6 shows the arrangement of x and y gradient coils according to the second example;

FIG. 7 is a graph showing the gradient of the z component magnetic field in the x direction for a first region along the x axis according to the second example;

FIG. 8 shows the gradient in the z direction for the first region along the x axis;

FIG. 9 shows the gradient in the x direction for a second region along the x axis;

FIG. 10 shows the gradient in the z direction for the second region along the x axis;

FIG. 11 shows the gradient in the x direction for a first region along the z axis according to the second example;

FIG. 12 shows the gradient in the x direction for a second region along the z axis; and

FIG. 13 shows the gradient in the x direction for the second region along the z axis.

### DESCRIPTION OF PREFERRED EMBODIMENTS

First and second examples of gradient magnetic field coil arrangements and their use according to the invention are now described. The second example describes a design of gradient coils for MRI which is particularly suitable for “open access” or “single sided” systems. Each example operates by adjusting the relative currents in different coils according to the position of the imaging plane in order to obtain specified gradient uniformity over that plane. This results in a smaller, lower-inductance coil system than would be the case for a coil system designed to produce the same uniformity over all the possible planes in the imaging volume.

It is usual to refer to non-uniformities of gradients in terms of the “orders” of a polynomial expansion of the magnetic induction. This description arises from the solution of Laplace's equation for the magnetic potential in terms of the associated Legendre polynomials, Pₙ^{m}:
∇²Ψ=0 whose solutions can be written:

$$ψ ( ρ , θ , ϕ ) = {\sum }_{n , m} {( \frac{ρ}{a} )}^{n} ( {A}_{m}^{n} cos ( m ϕ ) + {B}_{m}^{n} sin ( m ϕ ) ) {P}_{n}^{m} ( cos ( θ ) )$$

$$\vec{B} = - {μ}_{0} ∇ Ψ$$

$$B ( ρ , θ , ϕ ) = {μ}_{0} {\sum }_{l} {ρ}^{l} \{ \begin{matrix}{A}_{l} {P}_{l} ( cos θ ) + \\ {\sum }_{m} [ \begin{matrix}{C}_{l}^{m} cos m ϕ + \\ {S}_{l}^{m} sin m ϕ\end{matrix} ] {P}_{l}^{m} ( cos ϕ )\end{matrix} \}$$

where the coefficients A, B, C and S depend on the arrangement of conductors and m≦l.

The term containing the Legendre polynomials (Pₗ(cosθ)) represent cylindrically symmetric components, while the terms with the associated Legendre functions (Pₗ^{m}(cosθ)) describe the transverse gradients. Transforming to a Cartesian coordinate system, so that r=ρsinθ and x=rcosφ, y=rsinφ it can be seen that these functions vary with x and y. These must always occur in pairs (to satisfy the divergence theorem), the members of which have the same form, but offset from each other in the φ (azimuthal) direction by an angle of

$$\frac{π}{2 m} .$$

Terms with l=1 represent a linear gradient, with l=0 a field shift and with l>1 gradient impurities. In particular directions, the profile of the magnetic induction can be represented by Taylor series, and the values of the coefficients can be evaluated by fitting the results of numerical calculations to such series.

In a system consisting of several coils, which have different numbers of ampere-turns, the energy stored in the magnetic field can be obtained either from the inductance or by the calculation of:

$$\int \int {\int }_{all space} \frac{1}{2} B \cdot H ⅆ V$$

However, it is usually easier to use the inductance. For a system consisting of several independent coils, the inductance matrix can be calculated, if necessary using numerical methods, whose elements are the flux linking of coil i due to unit current in coil j:

$${M}_{i , j} = \frac{\int {\int }_{coili} {B}_{j} ⅆ A}{{I}_{j}}$$

The stored energy is then

$$W = {\sum }_{i , j} \frac{1}{2} {M}_{i , j} {I}_{i} {I}_{j}$$

This is a generalisation of the familiar result for a single coil

$$\frac{1}{2} {LI}^{ 2} .$$

Gradient coils are designed to produce sufficiently uniform gradients while minimising their stored energy. In most cases this results in complex systems which might consist of either a number of discrete windings whose dimensions and number of turns are chosen so that their gradient impurities cancel, or distributed windings where the spatial distribution of current is designed to achieve a similar effect.

Some examples of gradient coil systems are now described and it is shown how their function can be enhanced using the principle of “Adaptive Gradients”.

As a first example arrangement, consider a simple coil system for G_{z}. The simplest version is the “Maxwell pair” which consists of two circular coils, of radius α positioned at

$$z = \pm \frac{\sqrt{3}}{2} a$$

and energised in opposition. This position corresponds to a zero third order gradient and because of the anti-symmetry of the system there are no even-order gradients. The dominant non-uniformity is therefore fifth-order. The strength of the magnetic induction at position z is therefore

$${B}_{z} ( z ) \approx {B}_{1} \cdot z + {B}_{5} \cdot \frac{{z}^{5}}{5 !}$$

The strengths of the gradients per unit current are:

$${B}_{1} = \frac{0.6413 μ 0}{{a}^{2}}$$

$${B}_{3} = 0$$

$${B}_{5} = \frac{39.49 μ 0}{{a}^{6}}$$

If a uniformity of say 1% is required, then this is only satisfied where |z|<0.37α.

By adding a second pair of coils it is possible to cancel both third-order and fifth-order gradients. This can be done by positioning the members of these two pairs so that they have the same value of

$$\frac{{B}_{5}}{{B}_{3}} {a}^{2}$$

and then setting the number of ampere-turns in the ratio,

$$n = - \frac{{B}_{3} ( a , {b}_{1} )}{{B}_{3} ( a , {b}_{2} )}$$

where b₁, and b₂ are the z-positions of the two pairs of coils. It is also advantageous to choose these positions so that B₇ is small. Such a system has

$${b}_{1} = 0.39 a , \\ {b}_{2} = 1.1325 a , \\ \frac{{B}_{5}}{{B}_{3}} {a}^{2} = - 14.176 , \\ n = 8.385 .$$

The resulting gradients per unit current are:

$${B}_{1} = \frac{4.440 {μ}_{0}}{{a}^{2}}$$

$${B}_{3} = 0$$

$${B}_{5} = 0$$

$${B}_{7} = \frac{- 2249 μ}{{a}^{8}}$$

With this arrangement, the 1% uniformity volume is extended to |z|<0.75α. This arrangement of gradient coils is shown in FIG. 1a. The coils 1, 2 form a pair, as do coils 3, 4. Dashed lines indicate the axes of the system with their point of intersection marking the centre of the system and also that of the working region.

In accordance with the invention, using the principle of adaptive gradients, the working region can be further extended. Here the ampere-turns in each coil are optimised for a particular imaging plane, and re-adjusted for other planes. The currents within the gradient coils are controlled using suitable apparatus such as a controllable current supply as shown schematically at 100 in FIG. 1a.

FIG. 1b illustrates a suitable arrangement in more detail. Here a current supply 101 is connected in series opposition to the coils 1 and 2, whereas a separate current supply is connected in series opposition to coils 3 and 4. A control unit 103 sends respective signals to each of the current supplies 101, 102 so as to set their output currents. The control unit 103 sends the signals in response to a signal 104 that specifies the gradient strength and slice position. The signal 104 might originate from a system computer or pulse programmer. The required values of the currents are obtained by the control unit 103 from a lookup table.

If the imaging plane is situated at z=z′ and the required gradient is G_{z}, then the conditions to be satisfied are:
B_{z}(z′)=G_{z}·z′ to position the slice correctly in the data set;
B_{z}(z)≠G_{z}·z′for z≠z′ over the working volume to avoid aliasing;

$$\frac{\partial {B}_{z}}{\partial z} {\vert}_{z = {z}^{′}} \approx {G}_{z}$$

to achieve the correct slice thickness;

there may be other conditions, such as

$$\frac{{\partial }^{2} {B}_{z}}{\partial {x}^{2}} = 0$$

to eliminate curvature of the slice, that is so the field strength does not vary in a plane perpendicular to the gradient direction. In the case of the z-gradient with B₀=B_{z} we require that

$$\frac{\partial {B}_{z}}{\partial x}$$

be small over the field of view. On the central axis

$$\frac{\partial {B}_{z}}{\partial x}$$

is zero from symmetry, but may be expected to increase away from the axis. We therefore seek to control the on-axis value of

$$\frac{{\partial }^{2} {B}_{z}}{\partial {x}^{2}} .$$

To do this, we calculate the values of B₀, B₁ etc at z=z′ for each of the coils, and adjust the individual currents to achieve the conditions. The values of the various gradient orders can be calculated over a range of slice positions from the geometry of the coils. The simultaneous equations can then be solved for the coil currents to satisfy the conditions set out above.

To achieve the same gradient,

$${B}_{1} = \frac{4.440 μ o}{{a}^{2}}$$

at, for example, z′=1.0a and z′=1.1a we can use the following currents:

| z′ | Coil 1 | Coil 2 | Coil 3 | Coil 4 |
|---|---|---|---|---|
| 0 | 1 | −1 | 8.3846 | −8.3846 |
| 1.0a | −5.5278 | 5.5278 | 12.497 | −12.497 |
| 1.1a | −11.672 | 11.672 | 15.680 | −15.680 |

Here the values given for the coils are relative ampere-turns values with respect to unity.

To see the advantage in this we can consider a specific example:

Suppose that the radius a is 0.25 metres and that we require a gradient of 0.01 Tesla/metre.

The required ampere-turns values are then:

| z′ | Coil 1 | Coil 2 | Coil 3 | Coil 4 | Stored Energy J |
|---|---|---|---|---|---|
| 0 | 102.01 | −102.01 | 939.18 | −939.18 | 1.428 |
| 1.0a | −619.18 | 619.18 | 1399.8 | −1399.8 | 3.425 |
| 1.1a | −1307.4 | 1307.4 | 1756.4 | −1756.4 | 6.748 |

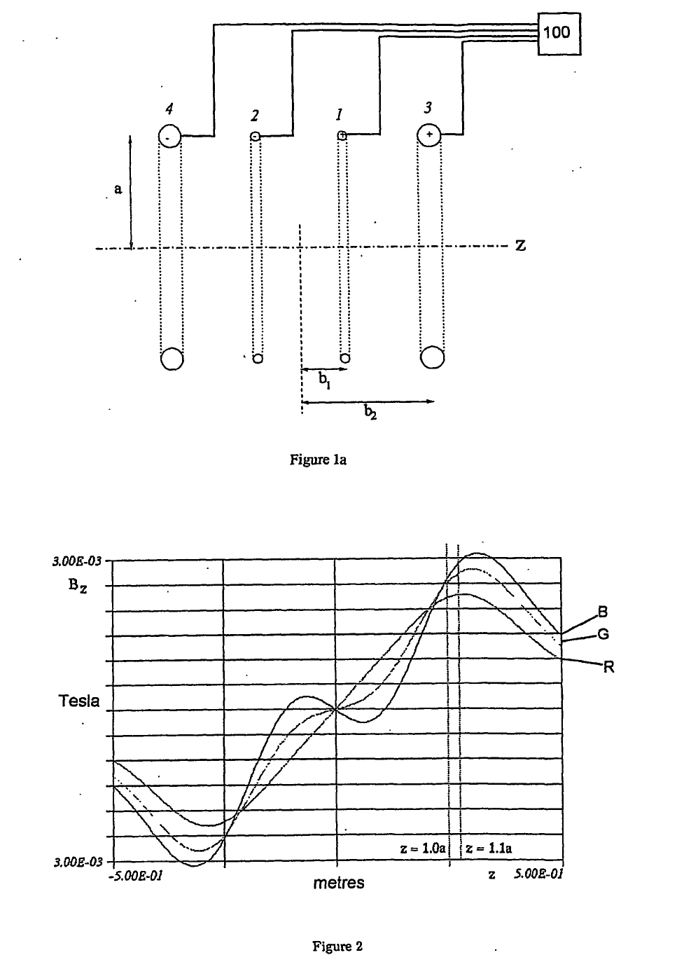

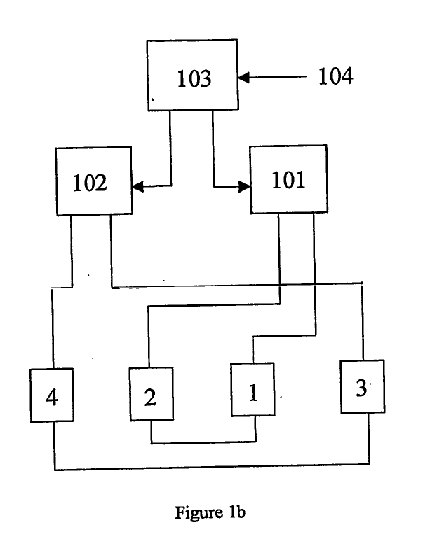

FIG. 2 shows the profile of the z component of the magnetic field as a function of the z-direction. The curve R represents the magnetic field resulting from the use of the gradient coils 1 to 4 in a conventional manner. It can be seen that an extensive region of approximately constant gradient is provided, although at a position of +1.0a and −1.0a, the gradient is significantly reduced as the curve approaches the respective turning point in each case. The curves G and B are those for the adapted gradients that meet the conditions given above. They correspond to imaging planes at z=1.0a and z=1.1a (0.25 m and 0.275 m respectively). The gradient of the curve G at the position z=1.0a and that of the curve B at z=1.1a is approximately the same as the gradient for the curve R within the central region. Although this is not essential it does simplify the processing needed to obtain the magnetic resonance information since it allows the “slice” thickness to be the same as in other parts of the working region.

It will also be noted that the gradients of the curves within the central region for both the curve G and B vary significantly, that of curve B even passing through turning points. This is a very counter-intuitive step to use in systems where it has always been understood that a constant gradient is required across the working volume. However, this does emphasise the fact that it is only the gradient within the particular region of interest (the imaging plane or slice) that is important during the read-out of magnetic resonance information.

By way of contrast, if it were desired to extend the volume of uniformity (corresponding to the central part of the curve R) of the conventionally used system, the system would need to be made larger. For example to extend it from 0.188 m to 0.25 m it would have to be 33% larger, and the ampere-turns would have to be increased by 1.33²=1.778. The inductance also will increase in proportion to the size, so that the stored energy (½LI²) can be expected to increase as the 5th power of the linear dimensions. Thus in this case the stored energy increases by a factor of 4.2, which is considerably more than under the “adaptive gradients” scheme described here.

In summary, in this example, adaptive gradients provide benefits in terms of overall size (which may be important inside a solenoid magnet) and in terms of stored energy, and consequently the switching time.

A second example system is now described, preferably for use with a “single sided” main magnet configuration. As a consequence, a single sided z-gradient system is used.

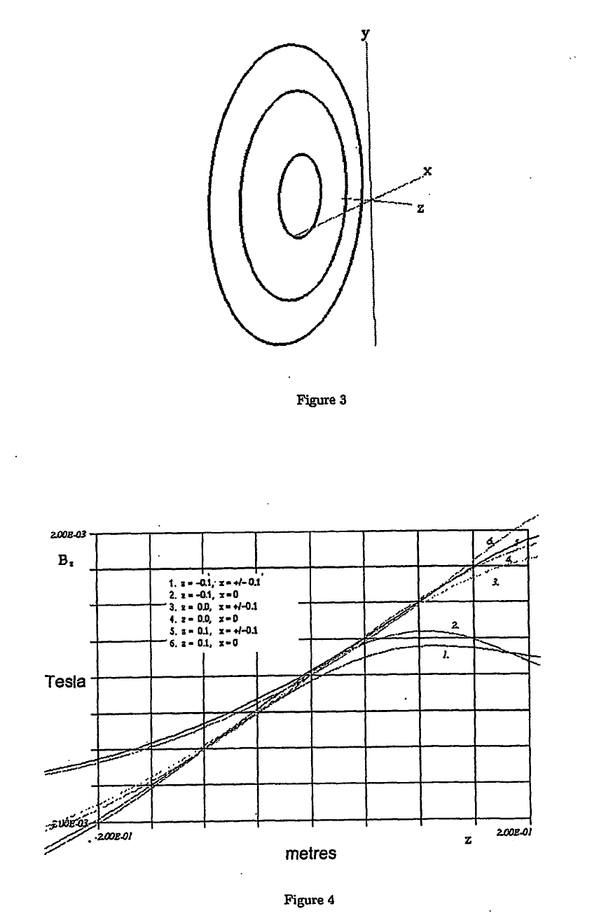

Problems of uniformity and stored energy are particularly acute in “single sided”, open-access systems because the absence of symmetry in the z-direction requires the use of counter-running coils which are inherently inefficient. Such a gradient coil system according to this second example is shown in FIG. 3. It consists of three co-axial coils, approximately coplanar, offset from the centre of the field of view.

Firstly considering slice selection in the z-direction, with B₀=B_{z}, if the required nominal gradient for slice selection is G_{z} and the slice is at z=z′ we require the z-gradient coil to be optimised for:

B_{z}=G_{z}×z′ The gradient appears linear and the slice appears at the correct position;

$$\frac{\partial {B}_{z}}{\partial z} {\vert}_{z = {z}^{′}} = {G}_{z}$$

The local slope is correct so the slice width is as expected;

$$\frac{{\partial }^{2} {B}_{z}}{\partial {x}^{2}} {\vert}_{z = {z}^{′}} = 0$$

The curvature is controlled.

There are three conditions to be satisfied, and so at least three coils are used, the currents within which are the variables for optimisation. We also require that there should be no aliasing, as before, that is that the value G_{z}×z′ does not occur anywhere else in the field of view.

As an example, consider this system, which has coil radii of 0.25, 0.7 and 1.0 m. They are positioned at z=−0.25 m. The coils are coplanar in this example, although this is not essential.

The field profiles in the z-direction are shown in FIG. 4: the lines labelled 1 and 2, 3 and 4, 5 and 6 represent optimisation in the three planes at −0.1, 0.0 and 0.1 m, respectively, away from and on the axis.

If we now assume that slice selection is in the x-direction (but the field is still in the z-direction), then we want to optimise the z-gradient over a series of z-y planes at successive values of x. The conditions for optimisation are:

B_{z}(u,0,0)=0 zero field in the middle of the plane;

$$\frac{\partial {B}_{z}}{\partial z} = {G}_{z}$$

the gradient has the correct value;

$$\frac{{\partial }^{2} {B}_{z}}{\partial {z}^{2}} {\vert}_{x = {x}^{′}} = 0$$

the gradient is linear in the selected plane at x=x′.

Taking the same system as above, it is possible to adjust the currents to optimise the z-gradient in various planes at different values of x.

| Plane | Z′ = −0.1 m | | | Z′ = 0 | | | Z′ = 0.1 m | | |
|---|---|---|---|---|---|---|---|---|---|
| radius (m) | 0.25 | 0.70 | 1.0 | 0.25 | 0.70 | 1.0 | 0.25 | 0.70 | 1.0 |
| Ampere- | −1.18E+3 | 2.74E+3 | −3.41E+4 | 1.54E+2 | 1.90E+4 | −2.50E+4 | 8.00E+4 | 9.25E+3 | 1.32E+4 |
| turns (NI) | | | | | | | | | |
| z = | −0.1 | 0.0 | 0.1 | −0.1 | 0.0 | 0.1 | −0.1 | 0.0 | 0.1 |
| B_{z} T | −1.00E−2 | −7.54E−5 | −3.92E−4 | −9.63E−4 | 1.75E−6 | 9.57E−4 | −6.46E−4 | 6.43E−5 | 1.00E−3 |
| $\frac{\partial {B}_{z}}{\partial z} {Tm}^{- 1}$ | 9.99E−3 | 7.76E−3 | 1.13E−3 | 8.96E−3 | 1.00E−2 | 8.59E−3 | 5.90E−3 | 8.33E−3 | 1.00E−2 |
| $\frac{{\partial }^{2} {B}_{z}}{\partial {x}^{2}} {Tm}^{- 2}$ | −1.29E−7 | 2.37E−2 | 3.62E−2 | −9.47E−3 | 2.82E−7 | 1.52E−2 | −1.16E−2 | −1.22E−2 | 3.15E−6 |

| | | | |
|---|---|---|---|
| W (Joules) | 5.89E+3 | 3.09E+3 | 8.31E+2 |

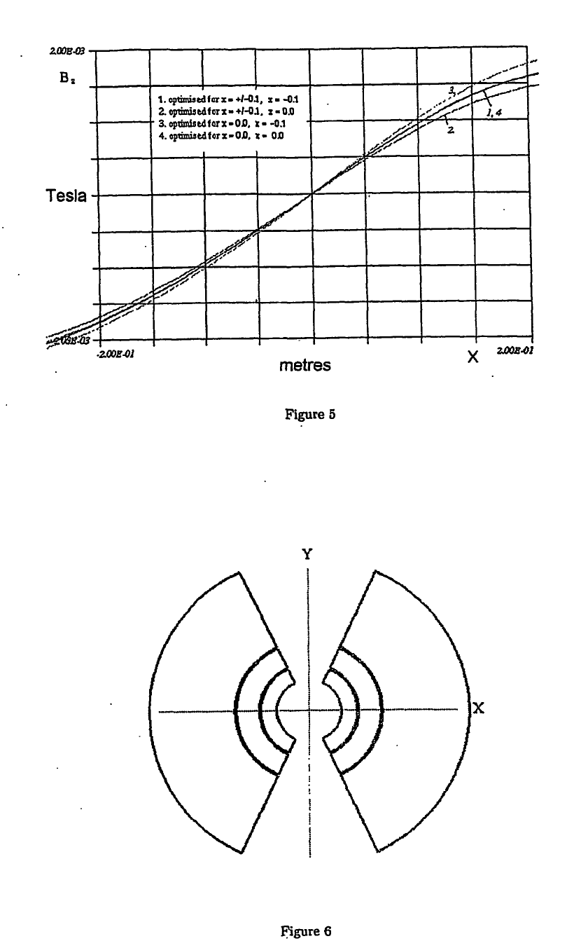

The field profiles for this are shown in FIG. 5. It should be noted that the variation in the y-direction is the same as that in the x-direction because of the symmetry of the system. Use of adaptive gradients for slice selection in the x-direction is therefore appropriate when we wish to extend the working volume in the x-direction, but are prepared to restrict it in the y-direction.

For single sided x and y gradients with slice selection in the x-direction, in general the x- (and y-) gradient coils should consist of two or three pairs of coils, in order to satisfy the conditions:

$${B}_{z} {\vert}_{x = {x}^{′}} = {G}_{x} \times {x}^{′}$$

$$\frac{\partial {B}_{z}}{\partial x} {\vert}_{x = {x}^{′}} = {G}_{x}$$

$$\frac{\partial {B}_{z}}{\partial {z}_{x = {x}^{′}}} = 0.$$

A typical arrangement is shown in FIG. 6. Each coil is characterised by an inner and an outer radius, r₁ and r₂ and a half-angle θ as well as the number of ampere-turns.

The following table shows the currents required for optimising such a coil system for different values of x′.

| Plane | Z′ = −0.1 m | | | Z′ = 0 | | |
|---|---|---|---|---|---|---|
| radius (m) | 0.25 m | 0.70 m | 1.0 m | 0.25 m | 0.70 m | 1.0 m |
| Ampere- | 7.88E+1 | 1.84E+4 | −2.42E+4 | 1.54E+2 | 1.90E+4 | −2.50E+4 |
| turns (NI) | | | | | | |
| x = | −0.1 m | 0.0 | 0.1 m | −0.1 m | 0.0 | 0.1 m |
| $\frac{\partial {B}_{z}}{\partial z} {Tm}^{- 1}$ | 1.00E−2 | 9.38E−3 | 1.00E−2 | 1.06E−2 | 1.00E−2 | 1.06E−2 |

| | | |
|---|---|---|
| W (Joules) | 2.90E+3 | 3.09E+3 |

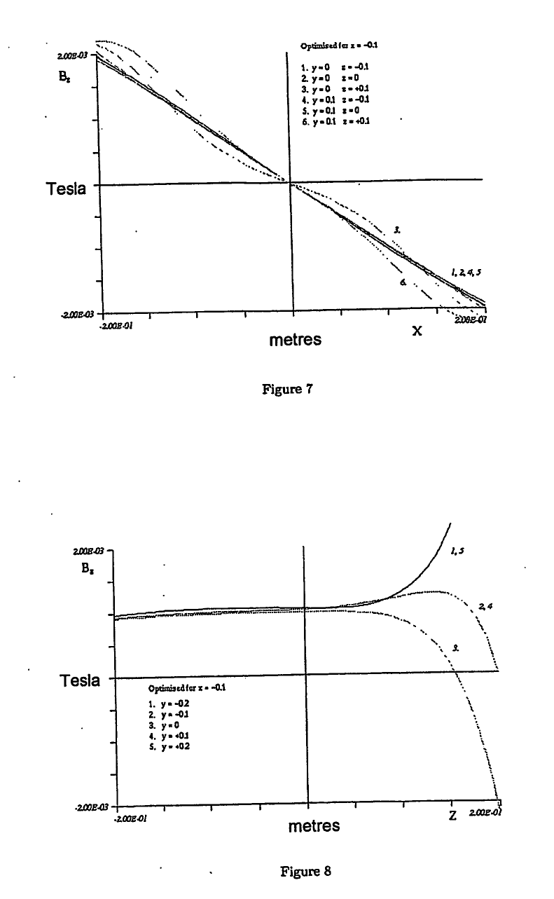

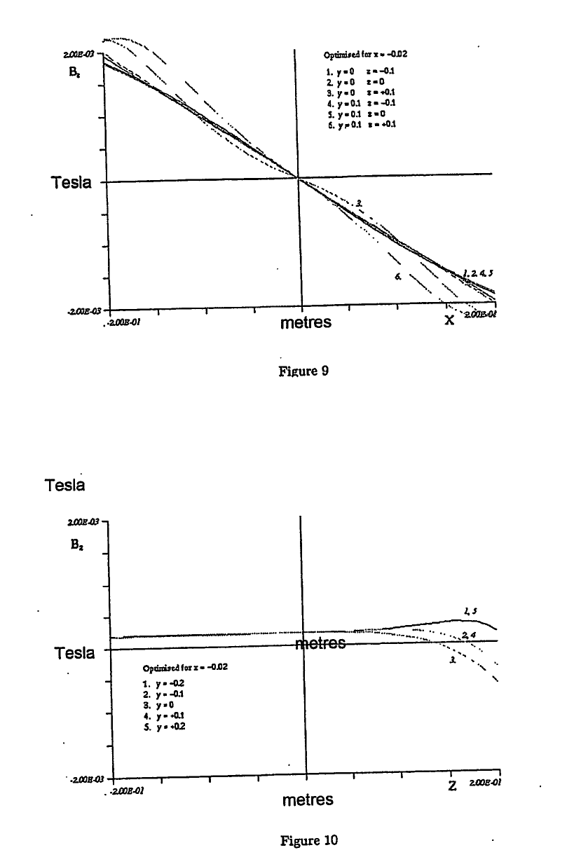

The FIGS. 7 to 10 show plots of B_{z} vs x at different values of y and z and plots of B_{z} vs z at different values of y for systems optimised for imaging planes at x′=0.1 m and x′=0.02 m.

In the case of slice selection in the z-direction we aim to optimise the currents in the same coils using

$${\frac{\partial {B}_{z}}{\partial x} \vert}_{z = {z}^{′}} = {G}_{x}$$

the gradient has the required value;

$$\frac{{\partial }^{2} {B}_{z}}{\partial {x}^{2}} {\vert}_{z = {z}^{′}} = 0$$

the gradient is linear;

$$\frac{{\partial }^{2} {B}_{z}}{\partial {y}^{2}} {\vert}_{z = {z}^{′}} = 0$$

no distortion in the transverse direction at different values of z successively.

The results of the calculations are:

| z′ m | NI₁ | NI₂ | NI₃ | W Joules |
|---|---|---|---|---|
| −0.1 | 10903.78 | 3030.42 | −586.32 | 1.272E+02 |
| 0.0 | 5495.30 | 2408.68 | −1934.47 | 5.815E+01 |
| 0.1 | 3429.03 | 2328.15 | −3192.89 | 7.486E+01 |

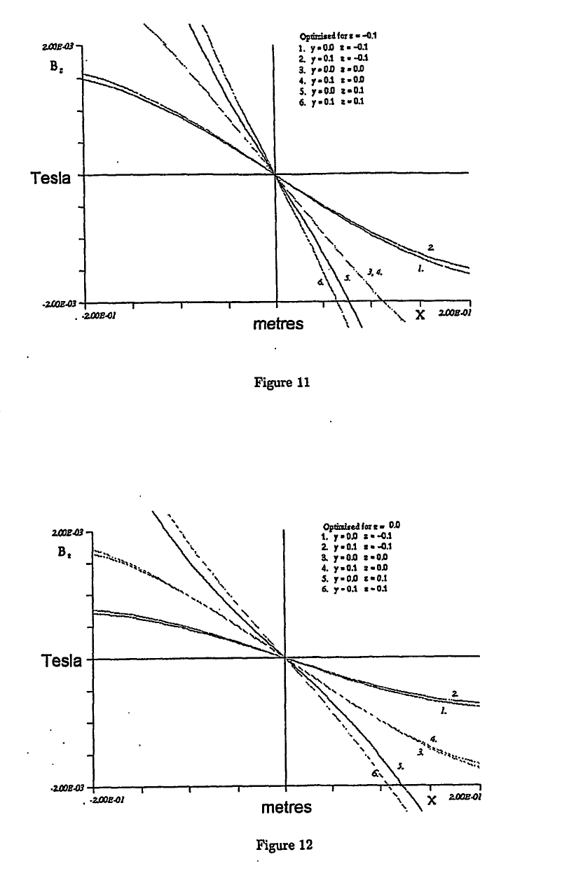

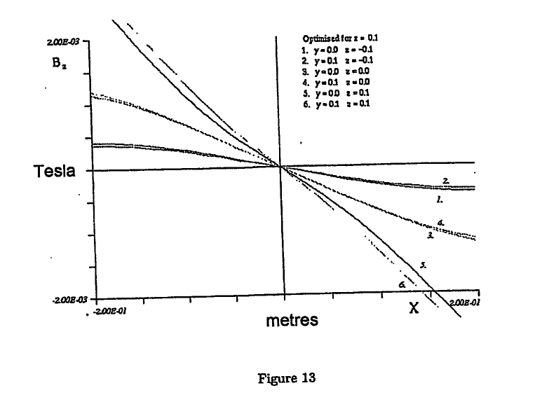

The profiles for these three optimisations are shown in FIGS. 11 to 13.

In summary, in designing gradient coils for MRI, it is possible to optimise the gradient uniformity over different imaging planes in succession, rather than over the entire field of view. Such coil systems consist of two or more component coils whose ampere-turns can be adjusted independently. The ampere-turns in the component coils can be adjusted by varying the currents in the different coils or by changing the number of turns by switching additional turns in or out of the circuit, or by a combination of both. These Adaptive Gradient coil systems offer benefits of:
increased gradient uniformity over the imaging plane for a given coil size.
more compact coils for a given gradient uniformity
reduced stored energy and hence faster switching time when compared with conventional gradient coil arrangement.

Adaptive. Gradient coils have greater complexity in their controls and current supplies, but the current supplies need only have a lower rating than those of conventional systems by comparison. Adaptive Gradient coils also offer particular benefits for “open access” or “single sided” MRI systems, but can usefully be applied to conventional MRI when space inside the main magnet is at a premium.

1-21. (canceled)

22. A method of operating a magnetic resonance apparatus in which magnetic gradient coils are used to generate one or more magnetic field gradients in a working volume so as to define regions from which magnetic resonance signals are obtained in use from a target material; characterized in that,
a set of at least two magnetic gradient coils are provided for producing the magnetic field gradient in a particular direction, and in that, for each of the defined regions, the one or more magnetic field gradients are controlled in accordance with the position of the said region with respect to the gradient coils by controlling the ampere-turns values within the at least two coils of the set independently, so as to apply one or more magnetic field gradients of predetermined uniformity within the region.

23. A method according to claim 22, wherein the defined regions are arranged as a series of regions, such the combined volume of the regions substantially intersects a target volume of the target material, the target volume being a volume of the target material from which it is desired to obtain the magnetic resonance signals.

24. A method according to claim 23, wherein the one or more magnetic field gradients applied to a particular region are dissimilar to those applied to an adjacent region.

25. A method according to claim 23, wherein the magnetic field gradient uniformity within regions at the periphery of the working volume is thereby increased so as to allow improved magnetic resonance signals to be obtained from such regions.

26. A method according to claim 22, wherein the working volume is arranged to one side of the coils comprising the magnetic resonance apparatus, and wherein the regions are arranged in the working volume.

27. A method according to claim 22, wherein each region comprises a substantially planar slice.

28. A method according to claim 22, wherein the method further comprises, within a particular region, controlling the one or more magnetic field gradients in accordance with the location of the target material of interest within that region.

29. A method according to claim 28, wherein the regions are arranged along a Z axis defining the magnetic field direction of the magnetic resonance apparatus, and wherein, within a particular region, the magnetic field gradients are controlled along an X axis and/or a Y axis, the X and Y axes being substantially orthogonal to the Z axis.

30. A method according to claim 22, wherein when the region is situated at z=z′ then the desired gradient G_{z} is determined in accordance with the conditions:
B_{z}(z′)=G_{z}·z′ so as to position the slice correctly;
B_{z}(z)≠G_{z}·z′for z≠z′ over the working volume so as to avoid aliasing; and
$$\frac{\partial {B}_{z}}{\partial z} {\vert}_{ z = {z}^{′}} \approx {G}_{z}$$
to achieve the correct slice thickness;
wherein B_{z}(z′) is the B field in the z direction at the position z=z′ and wherein the Bo field is in the z direction.

31. A method according to claim 30 wherein the gradient is determined in accordance with the condition
$$\frac{{\partial }^{2} {B}_{z}}{\partial {x}^{2}} = 0$$
so as to eliminate curvature of the region.

32. A method according to claim 22, wherein when the region is situated at x=x′ then the desired gradient Gₓ is determined in accordance with the conditions:
B_{z}(x′)=Gₓ·x′ so as to position the slice correctly;
B_{z}(x)≠Gₓ·x′for x≠x′ over the working volume so as to avoid aliasing; and
$$\frac{\partial {B}_{z}}{\partial x} {\vert}_{x = {x}^{′}} \approx {G}_{x}$$
to achieve the correct slice thickness;
wherein B_{z}(x′) is the B field in the z direction at the position x=x′ and wherein the Bo field is in the z direction.

33. A method according to claim 32 wherein the gradient is determined in accordance with the condition
$$\frac{{\partial }^{2} {B}_{z}}{\partial {z}^{2}} = 0$$
so as to eliminate curvature of the region.

34. A magnetic resonance apparatus comprising:
a magnet system for generating a magnetic field in a working volume;
magnetic gradient coils for generating one or more magnetic field gradients in the working volume so as to define regions from which magnetic resonance signals are obtained from a target material; and
a controller for operating the magnetic gradient coils in use so as to apply one or more magnetic field gradients within each region, characterised in that
the magnetic gradient coils comprise a set of at least two magnetic gradient coils for producing the magnetic field gradient in a first direction, and in that,
for each of the defined regions, the controller is further adapted in use to control the one or more magnetic field gradients in accordance with the position of the said region with respect to the magnetic gradient coils by controlling the ampere-turns values within the at least two magnetic gradient coils of the set independently, such that the one or more magnetic field gradients have a predetermined uniformity within the region.

35. Apparatus according to claim 34, wherein a set of at least two magnetic gradient coils are provided for producing the magnetic field gradient in each of, a second direction, or a second and third direction respectively, wherein for each set the ampere-turns values of at least two of the said coils are independently controllable using the controller.

36. Apparatus according to claim 34, wherein the working volume is arranged to one side of the coils comprising the magnetic resonance apparatus, and wherein the regions are arranged in the working volume.

37. Apparatus according to claim 36, wherein the axes for the gradient coils are each arranged along a common direction.

38. Apparatus according to claim 37, wherein the gradient coils within one set are arranged coaxially.

39. Apparatus according to claim 38, wherein the set comprises at least 3 independently controllable Z gradient coils.

40. Apparatus according to claim 35, further comprising a controllable current supply for providing current independently to the at least two magnetic gradient coils within each coil set.
